(19) United States
(12) Patent Application Publication
(10) Pub. No.: US 2026/0164887 A1
(43) Pub. Date: Jun. 11, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventors: Yeran LEE, Yongin-si (KR); YEONGMIN LIM, Yongin-si (KR)

(21) Appl. No.: 19/281,825

(22) Filed: Jul. 28, 2025

(30) Foreign Application Priority Data
Dec. 11, 2024 (KR) 10-2024-0183455

(51) Int. Cl. H10H 29/49; H01L 25/16; H10H 29/01; H10H 29/41

(52) U.S. Cl. CPC H10H 29/49; H10H 29/012; H10H 29/41; H10W 90/00

(57) ABSTRACT

A display device includes a display panel including a display area in which a display element layer is disposed and a pad area spaced apart from the display area in a first direction, a plurality of pad electrodes disposed in the pad area of the display panel, and a flexible film electrically connected to the pad electrodes and including a first insulating layer including a flexible material, a plurality of conductive lines disposed on the first insulating layer, having different separation distances from the display element layer in the first direction in a plan view, and a second insulating layer disposed on the first insulating layer and covering the conductive lines.

### CROSS-REFERENCE TO RELATED APPLICATIONS

This application claims priority under 35 U.S.C. § 119 to Korean Patent Application No. 10-2024-0183455, filed on Dec. 11, 2024, the disclosure of which is incorporated by reference herein in its entirety.

### TECHNICAL FIELD

Embodiments of the present disclosure relate to a display device, a method of manufacturing the display device, and an electronic device including the display device.

### DISCUSSION OF RELATED ART

A display device may include a display panel for displaying images and a circuit board configured to transmit electrical signals to the display panel. The circuit board and the display panel may be electrically connected by a flexible film, which includes a plurality of conductive lines. A driving chip, which processes signals generated by the circuit board and transmits them to the display panel, may be mounted on the flexible film and electrically connected to the conductive lines.

### SUMMARY

Embodiments of the present disclosure provide a display device with improved reliability.

Embodiments of the present disclosure provide a method of manufacturing a display device.

Embodiments o of the present disclosure provide an electronic device including the display device.

A display device according to an embodiment of the present disclosure includes a display panel including a display area in which a display element layer is disposed and a pad area spaced apart from the display area in a first direction, a plurality of pad electrodes disposed in the pad area of the display panel, and a flexible film electrically connected to the pad electrodes and including a first insulating layer including a flexible material, a plurality of conductive lines disposed on the first insulating layer, having different separation distances from the display element layer in the first direction in a plan view, and a second insulating layer disposed on the first insulating layer and covering the conductive lines.

In an embodiment, the conductive lines may include a first conductive line having a first separation distance from the display element layer in the first direction and a second conductive line disposed apart from the first conductive line in a second direction intersecting the first direction and having a second separation distance different from the first separation distance in the first direction from the display element layer.

In an embodiment, a difference between the first separation distance and the second separation distance may be about 20 μm to about 50 μm

In an embodiment, one side of the flexible film adjacent to the display element layer may be parallel to a second direction intersecting the first direction

In an embodiment, one side of the flexible film adjacent to the display element layer and the display element layer may be spaced apart by about 20 μm to about 50 μm in the first direction.

In an embodiment, the display device may further include a driving chip disposed on the flexible film and configured to drive the display panel.

In an embodiment, the flexible film may be bent around an imaginary extension line extending in a second direction intersecting the first direction.

In an embodiment, the display panel may include an encapsulation layer covering an upper surface of the display panel and the flexible film is spaced apart from the encapsulation layer in a plan view.

A method of manufacturing a display device according to an embodiment of the present disclosure includes disposing a preliminary flexible film including a first preliminary insulating layer, preliminary conductive lines, and a second preliminary insulating layer on a stage, forming a flexible film including a first insulating layer, conductive lines, and a second insulating layer by concavely cutting one side of the above preliminary flexible film, and attaching the flexible film to a pad area of a display panel.

In an embodiment, in forming the flexible film, the flexible film may be cut using a mold.

In an embodiment, in forming the flexible film, the flexible film may be cut using a laser.

In an embodiment, after forming the flexible film, the conductive lines may be formed to include a first conductive line having a first separation distance from the display element layer of the display panel in the first direction and a second conductive line disposed apart from the first conductive line in a second direction intersecting the first direction and having a second separation distance different from the first separation distance in the first direction from the display element layer, and wherein a difference between the first separation distance and the second separation distance may be about 20 μm to about 50 μm.

In an embodiment, in attaching the flexible film to the pad area, the flexible film may be attached to the display panel by thermal compression at a temperature of about 170° C. to about 185° C.

In an embodiment, after attaching the flexible film to the pad area, one side of the flexible film may be formed to be parallel to a direction of one side of the display element layer.

In an embodiment, after attaching the flexible film to the pad area, the flexible film may be formed to be spaced apart from the display element layer by about 20 μm to about 50 μm in a plan view.

An electronic device according to an embodiment of the present disclosure includes a display device and a processor configured to drive the display device. The display device includes a display panel including a display area in which a display element layer is disposed and a pad area spaced apart from the display area in a first direction, a plurality of pad electrodes disposed in the pad area of the display panel, and a flexible film electrically connected to the pad electrodes of the display panel and including a first insulating layer including a flexible material, a plurality of conductive lines disposed on the first insulating layer, having different separation distances from the display element layer in the first direction in a plan view, and a second insulating layer disposed on the first insulating layer and covering the conductive lines.

In an embodiment, the conductive lines may include a first conductive line having a first separation distance from the display element layer in the first direction and a second conductive line disposed apart from the first conductive line in a second direction intersecting the first direction and having a second separation distance different from the first separation distance in the first direction from the display element layer, wherein the difference between the first separation distance and the second separation distance may be about 20 μm to about 50 μm.

In an embodiment, one side of the flexible film adjacent to the display element layer may be parallel to a second direction intersecting the first direction.

In an embodiment, one side of the flexible film adjacent to the display element layer and the display panel may be spaced apart by about 20 μm to about 50 μm in the first direction.

In an embodiment, the display panel may include an encapsulation layer covering an upper surface of the display panel, and the flexible film is spaced apart from the encapsulation layer in a plan view.

A display device according to an embodiment of the present disclosure may include a display panel including a display area in which a display element layer is disposed and a pad area spaced apart from the display area in a first direction, a plurality of pad electrodes disposed in the pad area of the display panel, and a flexible film electrically connected to the pad electrodes and including a first insulating layer including a flexible material, a plurality of conductive lines disposed on the first insulating layer, having different separation distances from the display element layer in the first direction in a plan view, and a second insulating layer disposed on the first insulating layer and covering the conductive lines.

Accordingly, the display device according to embodiments may include conductive lines having a concave shape at the ends in a plan view. Since the conductive lines have a concave shape, even if the flexible film expands during the manufacturing process of the display device, the flexible film may be formed apart from the display element layer. As a result, the flexible film and the display element layer do not contact, so that the display quality or quality reliability of the display device may be improved.

### BRIEF DESCRIPTION OF THE DRAWINGS

The above and other features of the present disclosure will become more apparent by describing in detail embodiments thereof with reference to the accompanying drawings.

FIG. 1 is a perspective view showing a display device according to an embodiment of the present disclosure.

FIG. 2 is a perspective view showing an embodiment of the components included in the display device of FIG. 1.

FIG. 3 is a cross-sectional view showing the display device of FIG. 2 from a side view.

FIG. 4 is a cross-sectional view showing an embodiment in which the flexible film of the display device of FIG. 3 is bent.

FIG. 5 is a cross-sectional view showing an embodiment of the display panel of FIG. 4.

FIG. 6 is a plan view showing an embodiment of the A region of FIG. 2.

FIG. 7 is a cross-sectional view taken along the I-I′ line of FIG. 6.

FIGS. 8, 9, 10, 11, 12, and 13 are views showing a manufacturing method of the display device of FIG. 2.

FIG. 14 is a block diagram showing an electronic device according to an embodiment of the present disclosure.

FIG. 15 are schematic diagrams showing various embodiments of the electronic device of FIG. 14.

### DETAILED DESCRIPTION

Embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

It will be further understood that the terms “comprises” and/or “comprising,”when used in this specification, specify a presence of stated features, integers, steps, operations, elements, and/or components, but do not preclude the presence or addition of one or more other features, integers, steps, operations, elements, components, and/or groups thereof.

In this specification, a plane may be defined by a first direction D1 and a second direction D2 that intersects the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

In modern display devices, flexible films may be used to electrically connect a driving circuit to the display panel. However, during manufacturing - for example, during thermocompression bonding—flexible films are subject to thermal expansion, which can cause the film to shift or deform. If not properly managed, this expansion may result in the film coming into unintended contact with the display element layer, leading to mechanical stress, electrical shorts, or degradation in display quality. Accordingly, there is a need for a structural design that maintains sufficient separation between the flexible film and the active display area, even under thermal or mechanical stress conditions.

Embodiments of the present disclosure address this need by introducing a display device in which the conductive lines on a flexible film are arranged at varying distances from the display element layer in a plan view. This variation in spacing imparts a concave geometry to the terminal edge of the flexible film, which may reduce the risk of contact during thermal expansion. By providing for the central portion of the film to be recessed relative to the outer edges, the device may maintain a controlled gap between the film and the display element layer, even when the film expands during bonding. This separation may be in the range of about 20 μm to about 50 μm and may aid in preventing electrical interference and ensuring high display reliability.

Thus, embodiments of the present disclosure may provide a non-uniform conductive line layout and a concave terminal edge profile of the flexible film, which together provide a structural solution to a longstanding manufacturing reliability issue. This geometry-based approach may improve yield, reduce failure rates, and enhance the long-term performance of the display device without requiring changes to underlying materials or fabrication equipment.

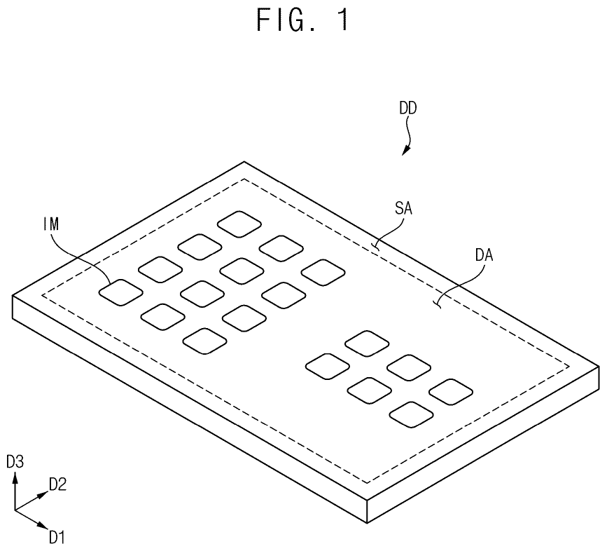

FIG. 1 is a perspective view showing a display device according to an embodiment of the present disclosure.

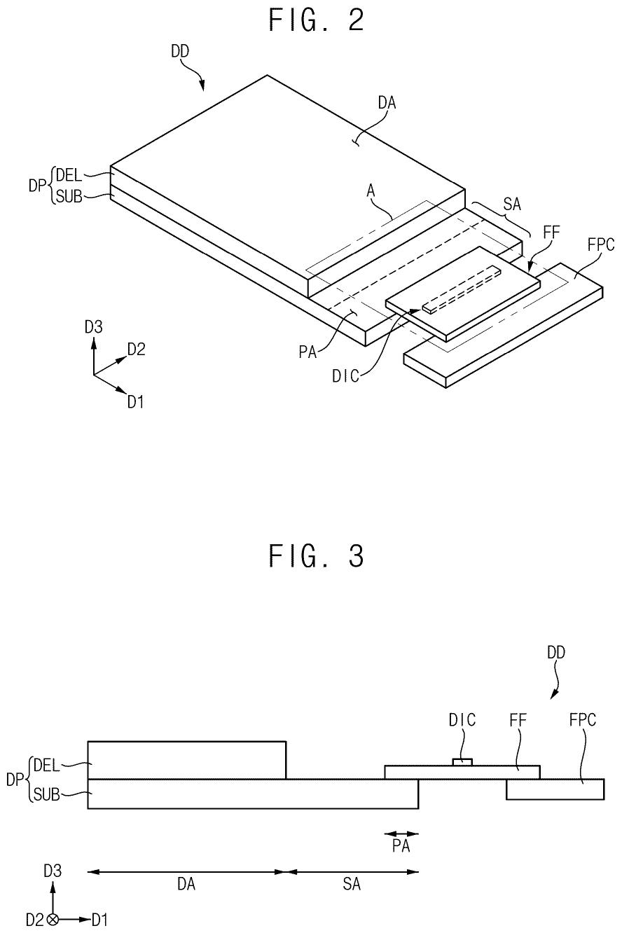

Referring to FIG. 1, the display device DD may include a display area DA and a peripheral area SA. The display area DA may be at least partially surrounded by the peripheral area SA. In FIG. 1, the peripheral area SA is shown as surrounding the display area DA however, embodiments of the present disclosure are not necessarily limited thereto. As shown in FIG. 2, the peripheral area SA may surround only one side of the display area DA.

The display area DA may be an area that generates light or controls a transmittance of light provided from an external light source to display images. The peripheral area SA may be a non-display area. However, embodiments of the present disclosure are not necessarily limited thereto, and at least a portion of the peripheral area SA may display images.

The display area DA may display multiple images IM, allowing users to receive information from the display device DD.

FIG. 2 is a perspective view showing an embodiment of the components included in the display device of FIG. 1. FIG. 3 is a cross-sectional view showing the display device of FIG. 2 from a side view.

Referring to FIGS. 1, 2, and 3, the display device DD may include a substrate SUB, a display element layer DEL, a flexible film FF, a driving chip DIC, and a circuit board FPC.

The substrate SUB may include, for example, glass, metal, plastic substrates, etc. However, embodiments of the present disclosure are not necessarily limited thereto, and the substrate SUB may be an inorganic layer, organic layer, or composite material layer.

In an embodiment, the substrate SUB may include a pad area PA spaced apart from the display area DA in the first direction D1. For example, as shown in FIG. 2, the pad area PA may be defined on one side of the peripheral area SA. That is, the substrate SUB may include the display area DA, the peripheral area SA surrounding at least a portion of the display area DA, and the pad area defined on one side of the peripheral area SA and spaced apart from the display area DA in the first direction.

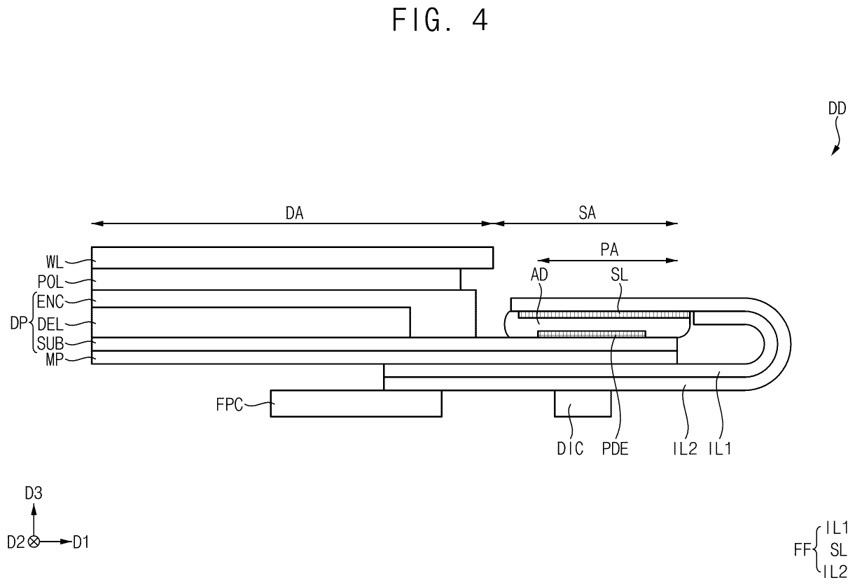

The pad area PA may be an area where the flexible film FF is attached to the substrate SUB. Multiple pad electrodes (for example, pad electrodes PDE of FIG. 4) may be disposed in the pad area PA. That is, the pad electrodes PDE of the substrate SUB may be electrically connected to the flexible film FF to receive external signals and apply the signals to the display element layer DEL.

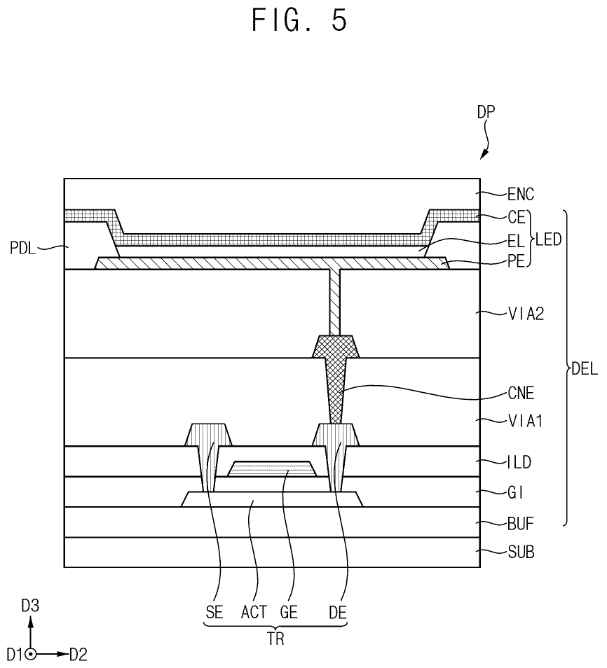

The display element layer DEL may be disposed on the substrate SUB. For example, the display element layer DEL may be disposed in the display area DA of the substrate SUB. The display element layer DEL may emit light to transmit a visual signal or the like to a user of the display device DD. The display element layer DEL will be described further below with reference to FIG. 5.

The circuit board FPC may be electrically connected to an electronic component (e.g., a timing controller). The circuit board FPC may generate a scan control signal, a data control signal, and image data using an image signal and multiple timing signals received from the electronic component. The generated scan control signal, data control signal, and image data may be provided to the driving chip DIC via the circuit board FPC.

One side of the flexible film FF may be attached to one side of the substrate SUB to exchange signals with the display element layer DEL. Additionally, the other side of the flexible film FF may be connected to the circuit board FPC, which drives the display element layer DEL. Accordingly, the circuit board FPC may exchange signals with the display element layer DEL through the flexible film FF.

In FIG. 2, the driving chip DIC is illustrated as being mounted on the flexible film FF in the display device DD, However, embodiments of the present disclosure are not necessarily limited thereto. The driving chip DIC may also be mounted on the substrate SUB of the display device DD. That is, the driving chip DIC may be mounted within the display device DD using methods such as, for example, chip on glass (COG), chip on film (COF), or chip on plastic (COP).

FIG. 4 is a cross-sectional view showing an embodiment in which the flexible film of the display device of FIG. 3 is bent.

Referring to FIGS. 3 and 4, the display device DD may include a metal plate MP, a display panel DP, a polymer layer POL, a window layer WL, the flexible film FF, the driving chip DIC, and the circuit board FPC. The display panel DP may include the substrate SUB, the display element layer DEL, and the encapsulation layer ENC.

The metal plate MP may be disposed under the display panel DP. The metal plate MP may support the display panel DP and protect the display device DD from external impacts. The metal plate MP may include a metal material. For example, the metal plate MP may include copper (Cu), aluminum (Al), or stainless steel (SUS). These may be used alone or in combination. However, embodiments of the present disclosure are not necessarily limited thereto.

The display panel DP may be disposed on the metal plate MP. That is, the substrate SUB, the display element layer DEL, and the encapsulation layer ENC may be sequentially disposed on the metal plate MP.

The substrate SUB may be disposed on the metal plate MP. As shown in FIG. 4, the substrate SUB may include a pad area PA defined by being spaced apart from the display area DA in the first direction D1. The pad electrode PDE may be disposed in the pad area PA. The electrical signals transmitted to the pad electrode PDE of the substrate SUB may be transmitted to the display panel DP. Accordingly, the display panel DP may emit light in response to the electrical signals.

The display element layer DEL may be disposed on the substrate SUB. The display element layer DEL may emit light to transmit visual signals to a user of the display device DD.

The encapsulation layer ENC may cover an upper surface of the display element layer DEL. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a polymeric cured material such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, or titanium oxide.

The polymer layer POL may be disposed on the display panel DP. The polymer layer POL may attach the display panel DP to the window layer WL. Additionally, the polymer layer POL may support the window layer WL to prevent it from sagging and may protect the display panel DP from external impacts. The polymer layer POL may have a single-layer or a multilayer structure.

The window layer WL may be disposed on the polymer layer POL. That is, a user of the display device DD may view the images IM through the window layer WL. For example, the window layer WL may include glass or plastic. These may be used alone or in combination. However, embodiments of the present disclosure are not necessarily limited thereto. Although FIG. 4 does not illustrate additional configurations on the window layer WL, functional layers such as a protective film or an anti-reflective film may be further disposed on the window layer WL.

The flexible film FF may be attached to the pad area PA of the substrate SUB. For example, the flexible film FF may adhere to the substrate SUB via an adhesive member AD. The adhesive member AD may have electrical conductivity and adhesiveness. Due to the conductivity of the adhesive member AD, electrical signals transmitted from the circuit board FPC may be delivered to the display panel DP. The adhesive member AD may be an anisotropic conductive film. However, embodiments of the present disclosure are not necessarily limited thereto.

The flexible film FF may include a first insulating layer IL1, conductive lines SL, and a second insulating layer IL2. For example, the flexible film FF may include the first insulating layer IL1, the conductive lines SL, and the second insulating layer IL2 sequentially disposed.

The first insulating layer IL1 may have flexibility. The first insulating layer IL1 may be bent around an imaginary extension line extending in the second direction D2. As the first insulating layer IL1 bends, the first insulating layer IL1 may overlap at least a portion of both upper and lower surfaces of the substrate SUB in a plan view. For example, the first insulating layer IL1 may include polyimide. However, embodiments of the present disclosure are not necessarily limited thereto.

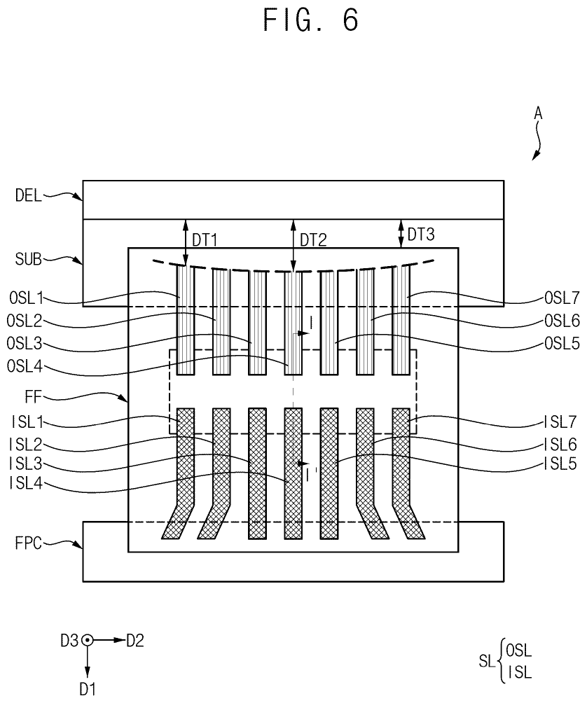

The conductive lines SL may be disposed on the first insulating layer IL1. The conductive lines SL may be electrically connected to the pad electrode PDE via the adhesive member AD. Accordingly, electrical signals transmitted from the circuit board FPC may be transmitted to the pad electrode PDE via the adhesive member AD. Arrangement and shape of the conductive lines SL will be described further below with reference to FIG. 6.

The second insulating layer IL2 may be disposed on the first insulating layer IL1 and may cover the conductive lines SL. Like the first insulating layer IL1, the second insulating layer IL2 may have flexibility. Accordingly, the second insulating layer IL2 may be bent around an imaginary extension line extending in the second direction D2. For example, the second insulating layer IL2 may include an insulating material such as a solder resist. However, embodiments of the present disclosure are not necessarily limited thereto.

The driving chip DIC may be disposed on the second insulating layer IL2. However, embodiments of the present disclosure are not necessarily limited thereto. The driving chip DIC may also be disposed on the first insulating layer IL1 or on the substrate SUB.

FIG. 5 is a cross-sectional view showing an embodiment of the display panel of FIG. 4.

Referring to FIGS. 4 and 5, the display panel DP may include the substrate SUB, the display element layer DEL, and the encapsulation layer ENC. The display element layer DEL may include a buffer layer BUF, a gate insulating layer GI, transistors TR, an interlayer insulating layer ILD, connection electrodes CNE, a first via layer VIA1, a second via layer VIA2, light-emitting diode LED, and a pixel defining layer PDL.

The transistors TR may include an active layer ACT, a gate electrode GE, a source electrode SE, and a drain electrode DE. The light-emitting diode LED may include pixel electrodes PE, an emitting layer EL, and a common electrode CE.

The substrate SUB may include a glass substrate, a metal substrate, or a plastic substrate. However, embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating through the substrate SUB to an upper portion of the substrate SUB. The buffer layer BUF may include an inorganic insulating material.

The active layer ACT may be disposed on the buffer layer BUF. The active layer ACT may include an oxide semiconductor, a silicon semiconductor, or an organic semiconductor. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon or polycrystalline silicon. The active layer ACT may include a source region, a drain region, and a channel region positioned between the source and drain regions.

The gate insulating layer GI may be disposed on the buffer layer BUF. For example, the gate insulating layer GI may cover the active layer ACT on the buffer layer BUF. The gate insulating layer GI may include an inorganic insulating material. In an embodiment, the gate insulating layer GI may be entirely disposed in the display area DA and the peripheral area SA. In another embodiment, the gate insulating layer GI may be disposed only under the gate electrode GE.

The gate electrode GE may be disposed on the gate insulating layer GI. The gate electrode GE may at least partially overlap the channel region of the active layer ACT. The gate electrode GE may include a conductive material such as metal, alloy, conductive metal nitride, conductive metal oxide, or a transparent conductive material. Examples of conductive materials usable for the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an aluminum-containing alloy, a silver-containing alloy, a copper-containing alloy, a molybdenum-containing alloy, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), and indium zinc oxide (IZO). These may be used alone or in combination. Optionally, the gate electrode GE may have a single-layer structure or a multilayer structure including multiple conductive layers.

An interlayer insulating layer ILD may be disposed on the gate electrode GE. For example, the interlayer insulating layer ILD may be disposed on the gate insulating layer GI and may cover the gate electrode GE on the gate insulating layer GI. The interlayer insulating layer ILD may include an inorganic insulating material. In an embodiment, the interlayer insulating layer ILD may be entirely disposed in the display area DA and the peripheral area SA.

A source electrode SE and a drain electrode DE may be disposed on the interlayer insulating layer ILD. The source electrode SE and the drain electrode DE may be connected to the active layer ACT. For example, the source electrode SE may be in contact with the source region of the active layer ACT, and the drain electrode DE may be in contact with the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. For example, the first via layer VIA1 may be disposed on the interlayer insulating layer ILD and may cover the source electrode SE and the drain electrode DE. The first via layer VIA1 may include an organic insulating material. In an embodiment, the first via layer VIA1 may be formed only in the display area DA and a portion of the peripheral area SA adjacent to the display area DA.

The connection electrode CNE may be disposed on the first via layer VIA1. The connection electrode CNE may transmit signals transmitted from the transistor TR to the light-emitting diode LED. The connection electrode CNE may include a conductive material such as metal, alloy, metal nitride, conductive metal oxide, or a transparent conductive material. These may be used alone or in combination. However, embodiments of the present disclosure are not necessarily limited thereto.

The second via layer VIA2 may be disposed on the connection electrode CNE. For example, the second via layer VIA2 may be disposed on the first via layer VIA1 and may cover the connection electrode CNE. The second via layer VIA2 may include substantially the same material as the first via layer VIA1.

The pixel electrode PE may be disposed on the second via layer VIA2. The pixel electrode PE may include a conductive material. The pixel electrode PE may be connected to the drain electrode DE via the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light-emitting layer EL may be disposed on the pixel electrode PE. In an embodiment, the light-emitting layer EL may be disposed in an opening defined by the pixel defining layer PDL. That is, the light-emitting layer EL may be surrounded by the pixel defining layer PDL. In an embodiment, the light-emitting layer EL may also be disposed on the pixel defining layer PDL. The light-emitting layer EL may include at least one of an organic light-emitting material and quantum dots. However, embodiments of the present disclosure are not necessarily limited thereto.

The common electrode CE may be disposed on the light-emitting layer EL. The common electrode CE may also be disposed on the pixel defining layer PDL. That is, the common electrode CE may be continuously disposed on the light-emitting layer EL and the pixel defining layer PDL. The common electrode CE may include a conductive material. The light-emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a polymeric cured material such as polyacrylate, epoxy resin, or silicone resin. The inorganic encapsulation layer may include, for example, silicon oxide, silicon nitride, silicon carbide, aluminum oxide, tantalum oxide, hafnium oxide, zirconium oxide, or titanium oxide.

FIG. 6 is a plan view showing an embodiment of the A region of FIG. 2.

Referring to FIGS. 2 and 6, the conductive lines SL of the flexible film FF may include input conductive lines ISL and output conductive lines OSL. The input conductive lines ISL may include first, second, third, fourth, fifth, sixth, and seventh input conductive lines ISL1, ISL2, ISL3, ISL4, ISL5, ISL6, and ISL7. The output conductive lines OSL may include first, second, third, fourth, fifth, sixth, and seventh output conductive lines OSL1, OSL2, OSL3, OSL4, OSL5, OSL6, and OSL7.

In FIG. 6, the conductive lines SL are shown to include seven input and output conductive lines, respectively, but embodiments of the present disclosure are not necessarily limited thereto. Each of the input conductive lines ISL and output conductive lines OSL may include six or fewer, or eight or more conductive lines.

The first, second, third, fourth, fifth, sixth, and seventh input conductive lines ISL1, ISL2, ISL3, ISL4, ISL5, ISL6, and ISL7 may be disposed on one side of the flexible film FF in the second direction D2. For example, as shown in FIG. 6, the second input conductive line ISL2 may be spaced apart from the first input conductive line ISL1 in the second direction D2. Similarly, the third input conductive line ISL3 may be spaced apart from the second input conductive line ISL2 in the second direction D2.

The input conductive lines ISL may receive electrical signals from the circuit board FPC and apply them to the driving chip DIC. The driving chip DIC may transmit signals to the output conductive lines OSL.

The first, second, third, fourth, fifth, sixth, and seventh output conductive lines OSL1, OSL2, OSL3, OSL4, OSL5, OSL6, and OSL7 may be disposed on one side of the flexible film FF in the second direction D2. For example, as shown in FIG. 6, the second output conductive line OSL2 may be spaced apart from the first output conductive line OSL1 in the second direction D2, and the third output conductive line OSL3 may be spaced apart from the second output conductive line OSL2.

In an embodiment, the input conductive lines ISL and output conductive lines OSL may correspond one-to-one. For example, the first input conductive line ISL1 may correspond to the first output conductive line OSL1, allowing electrical signals transmitted through ISL1 to be applied to OSL1 via the driving chip DIC.

Each of the output conductive lines OSL may be disposed apart from the display element layer DEL in a plan view. Additionally, each of the output conductive lines OSL may be disposed apart from the encapsulation layer (e.g., the encapsulation layer ENC of FIG. 5) in a plan view.

In an embodiment, each of the output conductive lines OSL may be spaced apart from the display element layer DEL by different distances in a plan view. For example, the first output conductive line OSL1 may have a first separation distance DT1 from the display element layer DEL in a plan view. The fourth output conductive line OSL4 may have a second separation distance DT2, which is different from the first separation distance DT1, from the display element layer DEL in a plan view.

As shown in FIG. 6, the first separation distance DT1 may be smaller than the second separation distance DT2. That is, a distance between the output conductive lines OSL and the display element layer DEL may be increased as the conductive lines are positioned at a center of the flexible film FF. As a separation distances of the output conductive lines OSL from the display element layer DEL vary, connecting ends of the output conductive lines OSL may define a concave curve in a plan view.

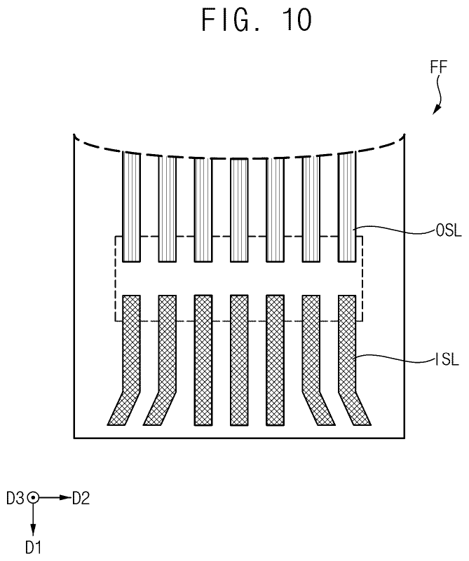

In an embodiment, a difference between the first separation distance DT1 and the second separation distance DT2 may be about 20 μm to about 50 μm. For example, a difference between the first separation distance DT1 and the second separation distance DT2 may be about 20 μm to about 40 μm. An effect that occurs when a difference between the first separation distance DT1 and the second separation distance DT2 has the above-described range may occur during a manufacturing process, and thus the effect will be described further below with reference to FIGS. 10, 11, 12, and 13.

In an embodiment, a third separation distance DT3, which is the separation distance between the flexible film FF and the display element layer DEL, may be about 20 μm to about 50 μm. For example, the flexible film FF and the display element layer DEL may be spaced apart by the third separation distance DT3 in the first direction D1 in a plan view. By being spaced apart by the third separation distance DT3, contact between the flexible film FF and the display element layer DEL may be prevented or reduced.

In an embodiment, one side of the flexible film FF adjacent to the display element layer DEL may be parallel to the second direction D2. That is, while the output conductive lines OSL may have a concave shape in a plan view, the first insulating layer IL1 and/or the second insulating layer IL2 of the flexible film FF may be parallel to one side of the display element layer DEL.

In an embodiment, the output conductive lines OSL disposed on the flexible film FF may be arranged such that each line is spaced apart from the display element layer DEL by a different distance in a plan view. That is, rather than terminating along a straight edge, in an embodiment, the output conductive lines are intentionally patterned with varying offsets relative to the display element layer DEL. For example, the first output conductive line OSL1, located toward the outer edge of the flexible film FF, may be separated from the display element layer DEL by a first separation distance DT1. In contrast, a more centrally located line, such as the fourth output conductive line OSL4, may be separated by a second separation distance DT2, which is greater than DT1. This graduated spacing across the width of the flexible film introduces a geometric curvature to the line terminations.

As shown in FIG. 6, the variation in separation distances among the output conductive lines produces a distinct pattern: the lines near the edges of the flexible film are closer to the display element layer, while those near the center are farther away. This distribution results in a concave arrangement of the conductive line ends in a plan view, effectively forming a recessed contour along the interface between the flexible film and the display panel. The concave shape may aid in accommodating thermal expansion during manufacturing, for example, during thermocompression bonding. Because expansion tends to occur most strongly at the center of the film, this shape may help maintain a consistent gap between the flexible film and the underlying display structure.

In an embodiment, the difference between the first and second separation distances DT1 and DT2 may be in the range of about 20 μm to about 50 μm, e.g., between about 20 μm and about 40 μm. This range may aid in achieving a balance between sufficient separation and manufacturability. A concave profile within this range may provide enough clearance to offset the dimensional changes that occur when the flexible film expands under heat and pressure. This effect may become beneficial during bonding processes, as further described with reference to FIGS. 10 through 13, where it can contribute to preventing mechanical contact and providing the structural and electrical integrity of the display.

In addition to the distance variation among individual conductive lines, the flexible film FF as a whole may also be spaced apart from the display element layer DEL by a third separation distance DT3, which may be about 20 μm to about 50 μm in the first direction D1 in a plan view. By maintaining this gap across the full interface, the configuration may reduce the likelihood of physical contact, thereby preventing potential electrical shorts, delamination, or damage to sensitive display components. This spacing may contribute to improved display reliability and manufacturing yield.

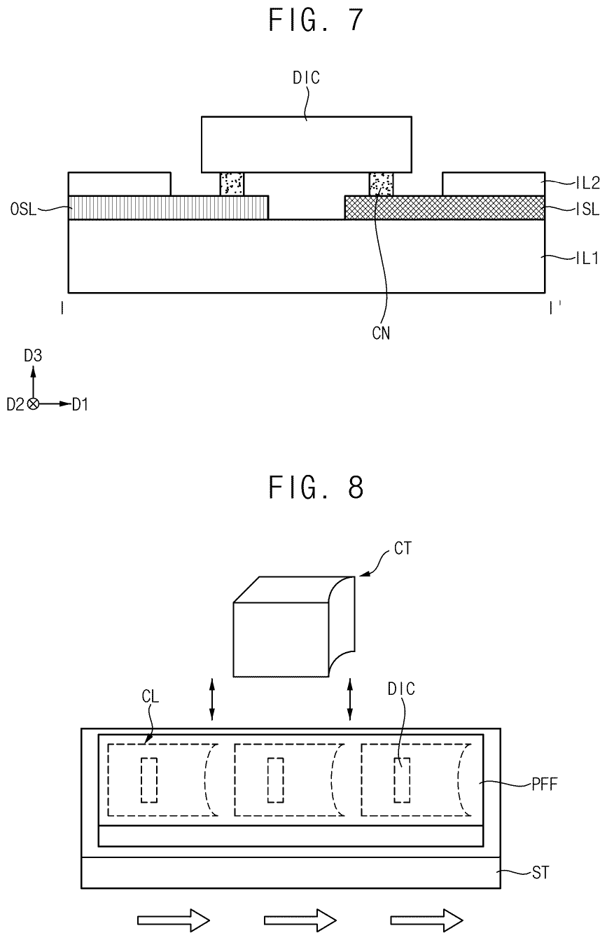

FIG. 7 is a cross-sectional view taken along the I-I′ line of FIG. 6.

Referring to FIGS. 6 and 7, the flexible film FF may be electrically connected to the driving chip DIC. For example, the input conductive lines ISL and output conductive lines OSL of the flexible film FF may be electrically connected to the driving chip DIC.

As shown in FIG. 7, each of the input conductive lines ISL and the output conductive lines OSL may be electrically connected to the driving chip DIC through contact electrode CN. That is, electrical signals transmitted through the input conductive lines ISL may be applied to the driving chip DIC through the contact electrode CN. Subsequently, the electrical signals transmitted from the driving chip DIC may be transmitted to the output conductive lines OSL through the contact electrode CN.

In FIG. 7, the contact electrode CN are illustrated as electrically connecting the driving chip DIC to the conductive lines SL, however, embodiments of the present disclosure are not necessarily limited thereto. The driving chip DIC and the conductive lines SL may also be electrically connected via an adhesive member (e.g., the adhesive member AD of FIG. 4).

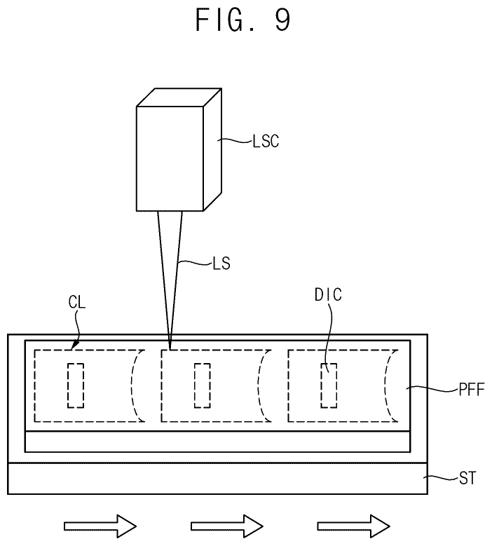

FIGS. 8, 9, 10, 11, 12, and 13 are views showing a manufacturing method of the display device of FIG. 2. For example, FIGS. 8 and 9 show a method of manufacturing the flexible film FF, while FIGS. 10, 11, 12, and 13 show an attachment of the flexible film FF to the display panel DP.

Referring to FIGS. 8 and 9, a preliminary flexible film PFF may be seated on (e.g., disposed on, or placed on) a stage ST. The preliminary flexible film PFF may include a first preliminary insulating layer, preliminary conductive lines, and a second preliminary insulating layer. For example, the preliminary conductive lines may be disposed on the first preliminary insulating layer, and the second preliminary insulating layer covering the preliminary conductive lines may be sequentially disposed thereon.

The preliminary flexible film PFF may be cut along a cutting line CL. As shown in FIGS. 8 and 9, the preliminary flexible film PFF may be cut along the cutting line CL to form the flexible film (e.g., the flexible film FF of FIG. 10).

In an embodiment, the cutting line CL may be defined with a concave shape on one side. Accordingly, the preliminary flexible film PFF may be cut along the cutting line CL to form a flexible film having a concave shape on one side in a plan view.

For example, referring to FIGS. 8 and 9, the preliminary flexible film PFF may be positioned on the stage ST for processing. The preliminary flexible film PFF may have a multilayer structure that includes a first preliminary insulating layer composed of a flexible material, a plurality of preliminary conductive lines disposed on the first preliminary insulating layer, and a second preliminary insulating layer sequentially formed on top of the conductive lines. The second preliminary insulating layer may serve to encapsulate and protect the conductive lines, providing electrical insulation and mechanical stability during subsequent handling and processing steps. This layered construction forms the basis for the flexible film that can later be tailored to accommodate thermal and spatial considerations in the final display device.

To achieve the desired geometry of the flexible film, the preliminary flexible film PFF may be cut along a predefined cutting line CL. As illustrated in FIGS. 8 and 9, the cutting process may transform the rectangular or otherwise uniform preliminary film into a precisely shaped flexible film (e.g., flexible film FF shown in FIG. 10) that can be attached to the display panel. The cutting line CL may be designed to follow a specific contour that imparts unique structural characteristics to the film, particularly along the edge where it interfaces with the display panel.

In an embodiment, the cutting line CL may be defined to include a concave profile along one edge of the flexible film, as viewed in a plan view. This concave shape may introduce a variation in the spacing between the conductive lines and the display element layer in the final assembled state. When the preliminary flexible film PFF is cut along this concave line, the resulting flexible film may exhibit a recessed or arched configuration at its terminal edge. This geometric profile may accommodate thermal expansion that may occur during thermocompression bonding, allowing the flexible film to remain spaced apart from the display element layer and thereby enhancing the mechanical integrity and electrical reliability of the final display device.

In an embodiment, as shown in FIG. 8, the preliminary flexible film PFF may be cut using a mold. For example, the preliminary flexible film PFF may be cut by a cutter CT included in the mold. For example, the cutter CT may move in an up-and-down direction while cutting the preliminary flexible film PFF. That is, as the stage ST moves the preliminary flexible film PFF in a direction intersecting the up-and-down direction, and the cutter CT moves in the up-and-down direction, the preliminary flexible film PFF may be cut along the cutting line CL.

In an embodiment, as shown in FIG. 9, the preliminary flexible film PFF may be cut by using a laser LS. For example, the preliminary flexible film PFF may be cut by the laser LS emitted from a laser oscillator LSC. That is, as the stage ST moves the preliminary flexible film PFF in one direction, and the laser LS is emitted from the laser oscillator LSC, the preliminary flexible film PFF may be cut along the cutting line CL.

Referring further to FIGS. 8, 9, and 10, the preliminary flexible film PFF may be cut by the cutter CT or the laser LS to form the flexible film FF. As one side of the preliminary flexible film PFF is cut in a concave shape, one side of the flexible film FF may also be formed in a concave shape. For example, when connecting the ends of the output conductive lines OSL of the flexible film FF with an imaginary line, a concave shape may be defined in a plan view. Consequently, the ends of the output conductive lines OSL, the first insulating layer IL1, and the second insulating layer IL2 of the flexible film FF may have a concave shape in a plan view.

The output conductive lines OSL shown in FIG. 10 may be substantially same to the output conductive lines OSL shown in FIG. 6 in a plan view. Thus, overlapping descriptions may be omitted.

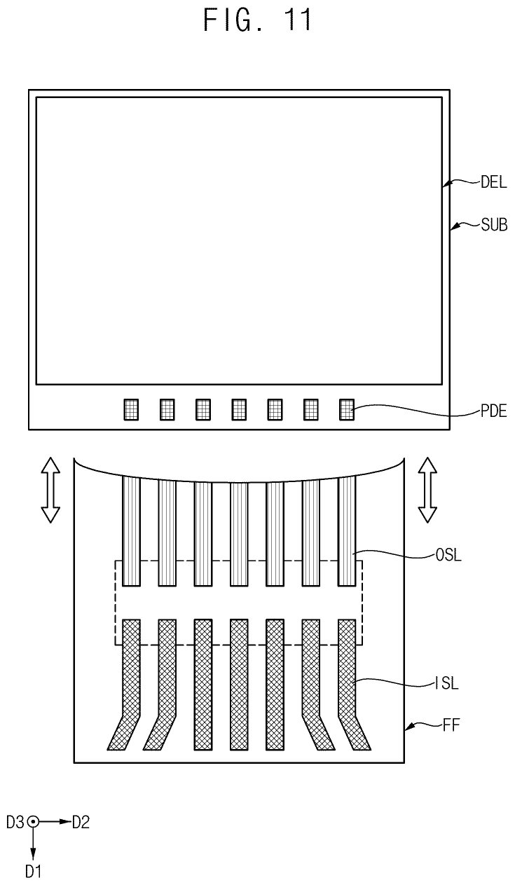

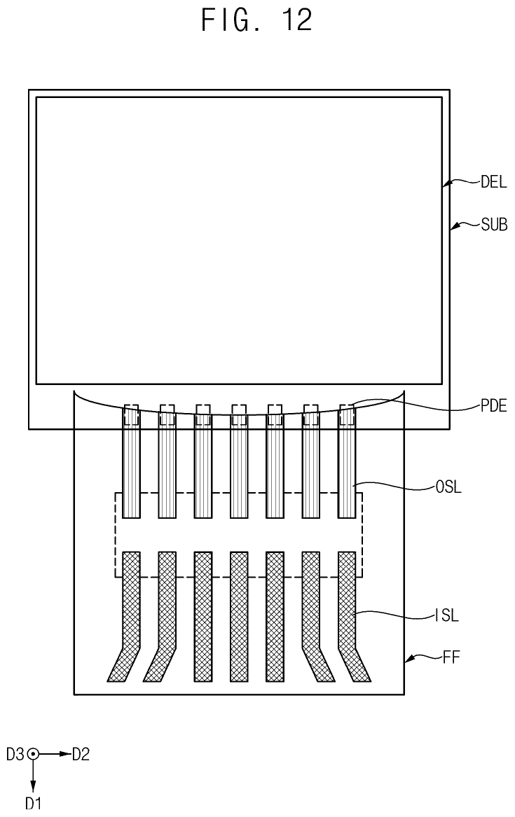

Referring further to FIGS. 11 and 12, one side of the flexible film FF, having a concave shape in a plan view, may be attached to the pad electrode PDE of the substrate SUB. The pad electrode PDE and the output conductive lines OSL may be attached in a one-to-one correspondence. The flexible film FF may be disposed apart from the display element layer DEL in a plan view.

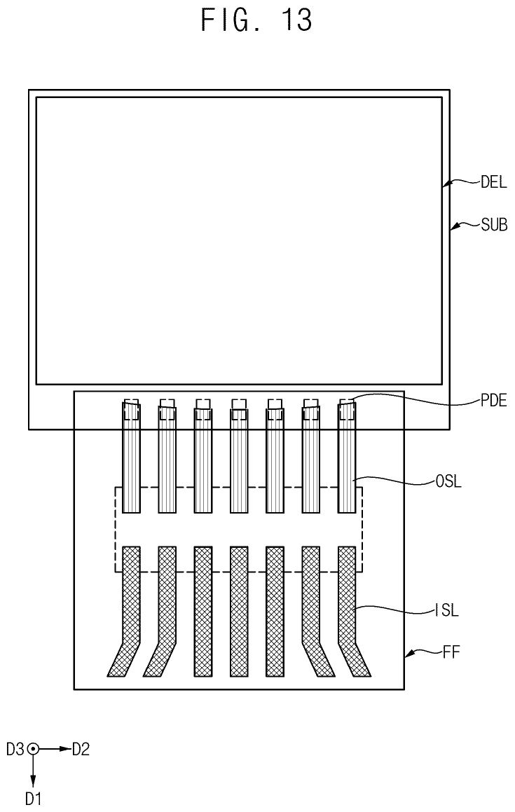

Referring further to FIGS. 12 and 13, the flexible film FF may be attached to the substrate SUB through thermocompression bonding. As the flexible film FF is attached to the substrate SUB through thermocompression bonding, one side of the flexible film FF may expand in a direction opposite to the first direction D1. Due to the expansion, a side of the flexible film FF adjacent to the display element layer DEL may become parallel to one side of the display element layer DEL.

In an embodiment, the flexible film FF may be attached to the substrate SUB through thermocompression bonding at a temperature of about 170° C. to about 190° C. For example, the flexible film FF may be attached through thermocompression bonding at a temperature of about 170° C. to about 185° C. If the flexible film FF is thermocompression bonded at a temperature higher than the specified range, excessive expansion may cause the flexible film FF to contact the display element layer DEL. Conversely, if thermocompression bonding occurs at a temperature lower than the specified range, the flexible film FF may not properly adhere to the substrate SUB.

In an embodiment, as shown in FIG. 13, even after the flexible film FF is thermocompression bonded to the substrate SUB, the flexible film FF and the display element layer DEL may remain spaced apart in a plan view. For example, the flexible film FF and the display element layer DEL may be spaced apart by about 20 μm to about 50 μm in the first direction D1 in a plan view. Since the flexible film FF and the display element layer DEL are spaced apart from each other in a plan view by the range described above, problems such as occurrence of a short circuit may be prevented or reduced.

Accordingly, the display device may include conductive lines with concave-shaped ends in a plan view. Due to the concave shape of the conductive lines, even if the flexible film expands during the manufacturing process of the display device, the flexible film may still be spaced apart from the display element layer. As a result, contact between the flexible film and the display element layer may be prevented, thereby improving the display quality and reliability of the display device.

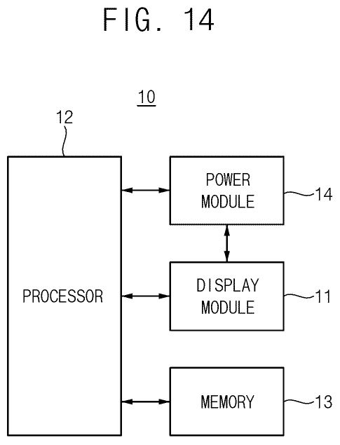

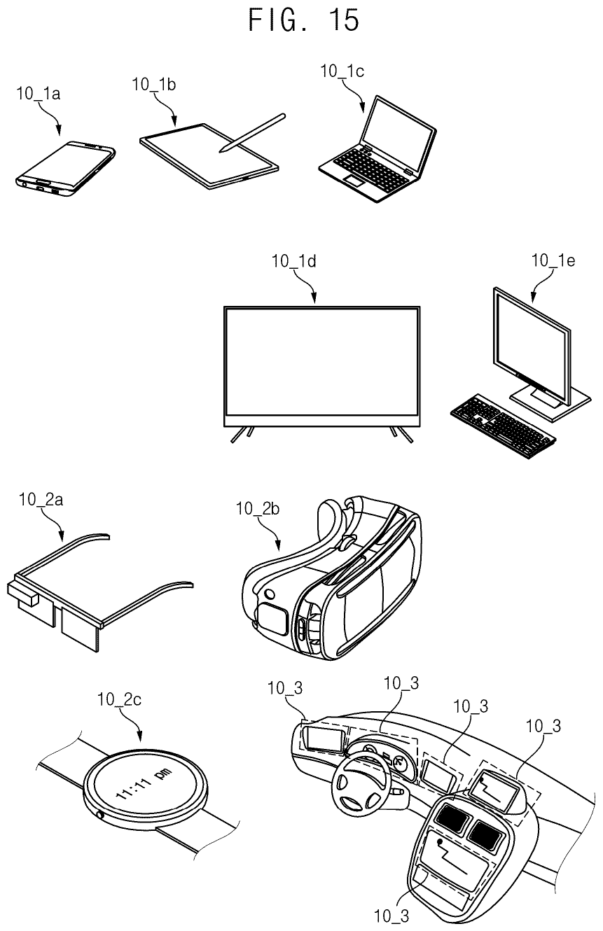

FIG. 14 is a block diagram showing an electronic device according to an embodiment of the present disclosure.

Referring to FIGS. 1 and 14, the display device DD according to embodiments of the disclosure may be applied to various electronic devices 10. An electronic device 10 according to an embodiment may include the display device DD and additional modules or devices providing other functionalities.

The electronic device 10 may include a display module 11, a processor 12, a memory 13, and a power module 14.

The processor 12 may include at least one of a central processing unit CPU, an application processor AP, a graphics processing unit GPU, a communication processor CP, an image signal processor ISP, and a controller.

The memory 13 may store data and information required for the operation of the processor 12 or the display module 11. When the processor 12 executes an application stored in the memory 13, video data signals and/or input control signals may be transmitted to the display module 11. The display module 11 may process the received signals to output video information on the display screen.

The power module 14 may include a power adapter, a battery device, and a power conversion module for generating the power required for the operation of the electronic device 10.

At least one component of the electronic device 10 described above may be included in the display device according to the embodiments of the disclosure. Some individual components functionally included in a module may be integrated into the display device, while others may be provided separately from the display device. For example, the display device DD may include the display module 11, while the processor 12, the memory 13, and the power module 14 may be provided as separate devices within the electronic device 10.

FIG. 15 are schematic diagrams showing various embodiments of the electronic device of FIG. 14.

Referring to FIGS. 14 and 15, various electronic devices 10 incorporating the display device DD may include image-display electronic devices such as smartphones 10_1a, tablet PCs 10_1b, laptops 10_1c, TVs 10_1d, and desktop monitors 10_1e. In addition, wearable electronic devices including display modules, such as smart glasses 10_2a, head-mounted displays 10_2b, and smartwatches 10_2c, and vehicle electronic devices including display modules, such as instrument clusters, center information displays (CID), and room mirror displays, may also be included.

However, these examples are illustrative, and the electronic device 10 according to the embodiments of the present disclosure is not necessarily limited thereto. For example, the electronic device 10 may be implemented as a mobile phone, videophone, smart pad, smartwatch, tablet PC, vehicle display, computer monitor, laptop, or head-mounted display device. Additionally, the electronic device 10 may be a television, monitor, laptop computer, or tablet. Furthermore, the electronic device 10 may also be a vehicle.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a display panel including a display area in which a display element layer is disposed and a pad area spaced apart from the display area in a first direction;
a plurality of pad electrodes disposed in the pad area of the display panel; and
a flexible film electrically connected to the pad electrodes and including:
a first insulating layer including a flexible material;
a plurality of conductive lines disposed on the first insulating layer, and having different separation distances from the display element layer in the first direction in a plan view; and
a second insulating layer disposed on the first insulating layer and covering the conductive lines.

2. The display device of claim 1, wherein the conductive lines include:
a first conductive line having a first separation distance from the display element layer in the first direction; and
a second conductive line disposed apart from the first conductive line in a second direction intersecting the first direction and having a second separation distance different from the first separation distance in the first direction from the display element layer.

3. The display device of claim 2, wherein a difference between the first separation distance and the second separation distance is about 20 μm to about 50 μm.

4. The display device of claim 1, wherein one side of the flexible film adjacent to the display element layer is parallel to a second direction intersecting the first direction.

5. The display device of claim 1, wherein one side of the flexible film adjacent to the display element layer and the display element layer are spaced apart by about 20 μm to about 50 μmin the first direction.

6. The display device of claim 1, further comprising:
a driving chip disposed on the flexible film and configured to drive the display panel.

7. The display device of claim 1, wherein the flexible film is bent around an imaginary extension line extending in a second direction intersecting the first direction.

8. The display device of claim 1, wherein the display panel includes an encapsulation layer covering an upper surface of the display panel, and
the flexible film is spaced apart from the encapsulation layer in the plan view.

9. A method of manufacturing a display device, comprising:
disposing a preliminary flexible film including a first preliminary insulating layer, preliminary conductive lines, and a second preliminary insulating layer on a stage;
forming a flexible film including a first insulating layer, conductive lines, and a second insulating layer by concavely cutting one side of the preliminary flexible film; and
attaching the flexible film to a pad area of a display panel.

10. The method of claim 9, wherein in forming the flexible film,
the flexible film is cut using a mold.

11. The method of claim 9, wherein in forming the flexible film,
the flexible film is cut using a laser.

12. The method of claim 9, wherein after forming the flexible film,
the conductive lines are formed to include:
a first conductive line having a first separation distance from a display element layer of the display panel in a first direction; and
a second conductive line disposed apart from the first conductive line in a second direction intersecting the first direction and having a second separation distance different from the first separation distance in the first direction from the display element layer, and
wherein a difference between the first separation distance and the second separation distance is about 20 μm to about 50 μm.

13. The method of claim 9, wherein in attaching the flexible film to the pad area,
the flexible film is attached to the display panel by thermal compression at a temperature of about 170° C. to about 185° C.

14. The method of claim 9, wherein after attaching the flexible film to the pad area,
one side of the flexible film is formed to be parallel to a direction of one side of a display element layer of the display panel.

15. The method of claim 9, wherein after attaching the flexible film to the pad area,
the flexible film is formed to be spaced apart from a display element layer of the display panel by about 20 μm to about 50 μm in a plan view.

16. An electronic device, comprising:
a display device; and
a processor configured to drive the display device, wherein the display device comprises:
a display panel including a display area in which a display element layer is disposed and a pad area spaced apart from the display area in a first direction;
a plurality of pad electrodes disposed in the pad area of the display panel; and
a flexible film electrically connected to the pad electrodes and including:
a first insulating layer including a flexible material;
a plurality of conductive lines disposed on the first insulating layer, and having different separation distances from the display element layer in the first direction in a plan view; and
a second insulating layer disposed on the first insulating layer and covering the conductive lines.

17. The electronic device of claim 16, wherein the conductive lines include:
a first conductive line having a first separation distance from the display element layer in the first direction; and
a second conductive line disposed apart from the first conductive line in a second direction intersecting the first direction and having a second separation distance different from the first separation distance in the first direction from the display element layer,
wherein the difference between the first separation distance and the second separation distance is about 20 μm to about 50 μm.

18. The electronic device of claim 16, wherein one side of the flexible film adjacent to the display element layer is parallel to a second direction intersecting the first direction.

19. The electronic device of claim 16, wherein one side of the flexible film adjacent to the display element layer and the display panel are spaced apart by about 20 μm to about 50 μmin the first direction.

20. The electronic device of claim 16, wherein the display panel includes an encapsulation layer covering an upper surface of the display panel, and
the flexible film is spaced apart from the encapsulation layer in the plan view.
